(19) United States
(12) Patent Application Publication
(10) Pub. No.: US 2005/0178495 A1
(43) Pub. Date: Aug. 18, 2005

(54) Method for transferring elements between substrates

(76) Inventors: Bernard Aspar, Rives (FR); Olivier Rayssac, Grenoble (FR); Frank Fournel, Morans (FR)

Correspondence Address: Thelen Reid & Priest, P O Box 640640, San Jose, CA, 95164-0640, US

(21) Appl. No.: 10/508,917

(22) PCT Filed: Mar. 21, 2003
(86) PCT No.: PCT/FR03/00905

(30) Foreign Application Priority Data
Mar. 25, 2002 (FR) 02/03693

(51) Int. Cl. H01L 21/68

(52) U.S. Cl. 156/230; 156/272.2

(57) ABSTRACT

The present invention relates to a method for transferring at least one element from a donor substrate to a target substrate (40). According to the invention, an element to be transferred is made integral with a handle substrate (30) through the intermediary of a layer of glue (32) capable of being degraded and in which degradation of the glue layer is carried out during a step for freeing the element to be transferred. Application to the transfer of components.

### TECHNICAL FIELD

The present invention relates to a method for transferring at least one element, such as a layer of material or a component, from a donor substrate to a target substrate. More precisely, it concerns a transfer method using an intermediate substrate, called a handle substrate.

The invention has applications in the manufacture of composite structures associating type III-V semiconductors and silicon. Other applications can be found in the manufacture of thin film substrates or in the transfer of components onto any supports whatsoever, and in particular onto small plates in plastic material.

### STATE OF PRIOR ART

The techniques for transferring a thin film from substrate to substrate are well known as such. As examples, documents (ref. 1) to (ref. 4) can be consulted, whose references are provided at the end of the present description.

The techniques for transferring fragile elements, such as thin films, usually make use of handle substrates that guarantee the maintenance of the thin films during transfer (ref. 4). The handle substrate is first made to adhere to a donor substrate and, more precisely, with a part of the donor substrate that is to be transferred. For instance, this can be a thin film. This part is then detached from the donor substrate and made to adhere to a target substrate. Finally, it is freed from the handle substrate.

Before being moved to the target substrate, the part to be transferred is integral with the handle substrate and can undergo various treatments.

In the transfer method as described, it is difficult to choose the means of adherence to be used to fix the part to be transferred onto the handle substrate. The adherence means must, in particular, be sufficiently strong so as to resist the stresses imposed by the treatments of the part to be transferred. They must also be sufficiently weak in order to be overcome when the part to be transferred is to be detached from the handle substrate. The imperatives of adhesive resistance and reversibility are antagonistic and involve difficulties for compromise.

Solutions have been envisaged using a handle substrate capable of being cleaved, or by eliminating the handle substrate by abrasion. However, these solutions are complex and increase the stresses imposed on the element to be transferred.

### DESCRIPTION OF THE INVENTION

The aim of the present invention is to provide a method without the difficulties and limitations indicated above.

A particular aim is to propose a method making it possible to answer both the requirements for firm adherence between an element to be transferred and a handle substrate, and for reversible adherence for final detachment from the handle substrate.

A further aim is to propose a method with a simple, inexpensive implementation, compatible with industrial production.

In order to achieve these aims, the invention has, more precisely, the aim of a transfer method for at least one element from a donor substrate to a target substrate, the element to be transferred being made integral with a handle substrate through the intermediary of a layer of glue capable of being degraded, where degradation of the layer of glue is carried out so as to free the element to be transferred. According to the invention, the method comprises the following successive steps:
a) gluing of the element to be transferred from the donor substrate onto the handle support by the intermediary of the glue layer,
b) treatment of the donor substrate and/or the element to be transferred,
c) degradation of the glue layer,
d) displacement of the element to be transferred onto the target substrate,
e) separation of the element to be transferred and the handle substrate.

The following description refers to a single element to be transferred. Nonetheless it should be noted that a plurality of elements can be transferred by means of a single or several handle substrates.

Within the meaning of the invention, it can be considered that the glue layer is able to be degraded, destructive means for the element to be transferred.

Elements capable of being transferred by the method according to the invention include layers of material, parts of layers, components, parts of components and, more generally, any element using techniques for microelectronics, micro-mechanics or integrated optics.

By degradation, one means any physical or chemical modification of the glue causing a modification of its mechanical hold compatible with ulterior separation.

It is to be emphasised that the gluing step requires, as indicated above, a layer of glue. Thus it excludes any direct molecular gluing. The glue to be used can be chosen from among an epoxy glue, a glue hardened by ultraviolet radiation, a polymer based glue, or a wax based glue.

The gluing step of the element to be transferred onto the handle support can be preceded by manufacturing this element on the donor substrate. It can furthermore be preceded by preparation of the donor substrate to encourage detachment of the element to be transferred, or otherwise by preparation of the interface between the donor substrate and the element to be transferred in order to obtain a controlled energy interface. An etched barrier layer can also be provided in the substrate.

As an example a fragilised area can be formed in the donor substrate by implanting ions. This zone can then be used later for cleaving in order to detach the element to be transferred. Cleaving can also serve to thin down the donor substrate. The technique for forming a fragilised zone for cleaving is known to those skilled in the art. Alternatively, the donor substrate can also be provided with an embedded sacrificial layer that can be eliminated to obtain the element to be transferred.

During step b), and thanks to the presence of the handle substrate, one or several of the following operations can, for example, be carried out:
thinning of the donor substrate,
separation of the layer to be transferred from the donor substrate,
cut-out of the donor substrate,
cut-out of the element to be transferred,
thinning of the element to be transferred,
separation of the element to be transferred and a remaining part of the donor substrate,
preparation of a transfer face for the element to be transferred.

Separation of the layer containing the element to be transferred from the donor substrate or from the element to be transferred with a remaining part of the donor substrate, can take place through cleaving or tearing in a fragilised zone, if such a zone has been prepared in the way indicated above. Separation can also take place by cutting out, for example with a saw. In a simpler way, the donor substrate, or even a part of the element to be transferred can be cut out or thinned. Thinning can, for example, be thinning by polishing or by abrasion. The abrasion can be mechanical and/or chemical.

A cut-out perpendicular to a free face of the element to be transferred can also be used for isolating or defining the limits of the components of the element to be transferred. The grooves or flanks resulting from cutting out can then be used later to facilitate degradation of the glue layer.

Preferably, the treatments employed take place when the element to be transferred is already glued on the handle substrate. Thus the handle substrate makes it possible to rigidify the element to be transferred and if need be to maintain cohesion. At the very least it gives it a mechanical resistance that suffices for withstanding the stresses caused by the treatment. It should be noted that any cutting out of the element to be transferred can extend through the handle substrate to define the limits of several smaller elements- to be transferred. These elements are then each associated with a handle substrate of size adapted to it, obtained by cutting out the initial handle substrate.

The displacement of the element to be transferred onto the target substrate and the degradation of the glue layer can take place in any order. Nonetheless, since glue degradation can lead to accidental premature separation, it is preferable to carry the element to the target substrate first, making it integral with this substrate.

The degradation of the glue layer can be activated depending on the type of glue used, by submitting it to a chemical treatment and/or a radiation treatment and/or a plasma treatment and/or a heat treatment.

Chemical treatment assisted by radiation is, for example, treatment of the UV-O₃ type (ozone obtained by using UV). For glue degradation by radiation, the handle substrate can advantageously be made of a material that is transparent to the radiation. The radiation is thus applied to the glue layer through the handle substrate.

In the same way, when degradation takes place by chemical means, it is advantageous to provide the handle substrate with channels for adding the chemical agent. The channels cross the support substrate from its free face as far as its face in contact with the glue layer.

Degradation of the glue layer results in making it fragile. Nonetheless, as indicated above, degradation of the glue layer does not, or at least not necessarily, lead to separation of the element to be transferred and the handle substrate.

The displacement of the element to be transferred onto the target substrate includes setting it into adherent contact with this substrate. Here again, it can consist of gluing using an intermediate layer of glue. However, the assembly can also be obtained by direct molecular adherence. In this latter case, the free face of the element to be transferred is prepared and cleaned in the appropriate manner, so that it has smooth and hydrophilic properties.

After displacement, and after degrading the glue layer linking the element to be transferred to the handle substrate, detachment of the latter takes place. Detachment can occur during the degradation step. It can be caused or assisted by using traction, pressure, shearing, peeling, or bending forces, or any combination of these forces. A jet of fluid and/or a tapered object can also be applied or inserted between the element to be transferred and the handle substrate, or even through the handle substrate if this has been processed. The component can also be separated from the handle substrate during its displacement onto the target substrate. This is the case, for example, when a punch through a handle substrate with a hole is used.

Another variant of the invention consists of separating the component from the handle substrate before displacing it onto the support. In this case a manipulator is used (for example a vacuum micro-pipette) to carry the element.

The transfer of elements can be collective or selective. It can even consist of transferring the entire plate. The gluing operations on the handle substrate and the treatment can be carried out collectively for an assembly of elements. The displacement and then the separation of the elements can then take place for a smaller sub-assembly of elements. These latter operations are then repeated for each sub-assembly of elements. In a particular application, components can be transferred one by one.

Other characteristics and advantages will become clear from the following description, with reference to the figures in the attached drawings. This description is given as a purely illustrative and non-limiting example.

### BRIEF DESCRIPTION OF THE FIGURES

FIG. 1 is a simplified diagrammatic cross-section of a donor substrate comprising elements to be transferred.

FIG. 2 is a diagrammatic cross-section of a structure comprising the donor substrate of FIG. 1 and a handle substrate.

FIGS. 3 and 4 are diagrammatic cross-sections of the structure of FIG. 2 and illustrate the steps of treatment and degradation.

FIG. 5 is a diagrammatic cross-section of a new structure obtained by assembling the structure of FIG. 4 with a target substrate. Arrows F indicate the detachment.

FIG. 6 is a diagrammatic cross-section of the structure of FIG. 5 after elimination of the handle substrate.

### DETAILED DESCRIPTION OF EMBODIMENTS OF THE INVENTION

In the following description, parts which are identical, similar or equivalent for the different figures are marked with the same references to facilitate the relationship between the figures. Moreover, and in order to clarify the figures, the elements are not represented on a uniform scale.

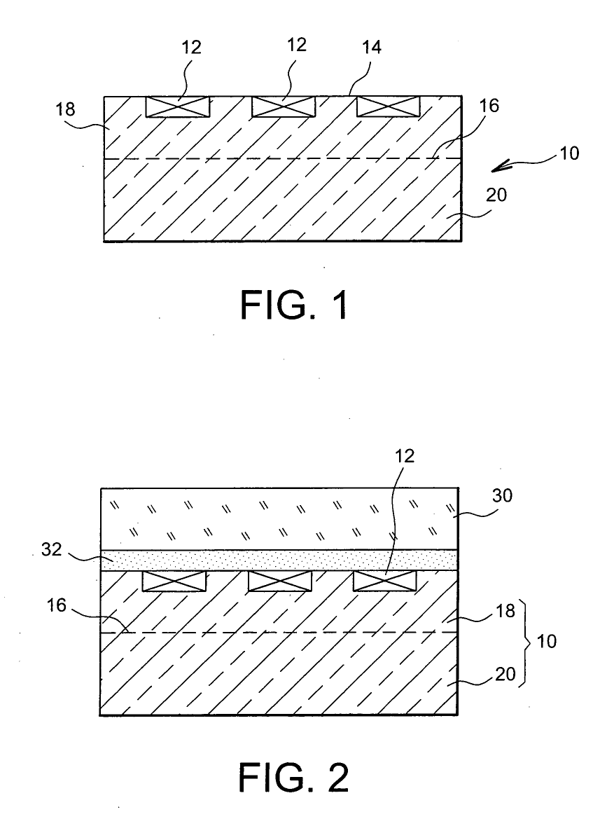

FIG. 1 shows a donor substrate 10 in which components 12 are formed. The latter are flush with a face 14 of the substrate. In the example illustrated, the donor substrate 10 is a solid substrate. It can, however, be replaced by a composite substrate of the silicon on insulator (SOI) or other type.

Reference 16 marks a zone of fragility that may be formed in the substrate by means of implantation of ions of a gaseous species. The technique consisting of forming a zone of fragility by implantation is well known to those skilled in the art and is therefore not described in detail here. This zone of fragility can also correspond to a gluing interface whose energy is controlled. The zone of fragility 16 defines the limits of an upper part 18 of the substrate comprising the components 12 and a remaining solid part 20 without components.

FIG. 2 shows the assembly of the substrate 10 with a handle substrate 30. The assembly is made by gluing using an intermediate layer of glue 32. For example, the glue is a glue of the cyanoacrylate type, that can be polymerised under the action of ultraviolet radiation. In the example described, the handle substrate 30 is thus made of a glass transparent to the radiation. The cyanoacrylate glue has the advantage of being able to be deposited in a particularly homogenous layer using a whirler. Furthermore, because of the photo-polymerising property of the glue, the assembly does not require application of any pressure.

The cyanoacrylate glue can be replaced by a wax or a resin (durimide) or a resin of the type used for lithography in microelectronics or by any other glue that can be degraded.

The thickness and the nature of the handle substrate 30 are chosen in such a way as to ensure good rigidity and to protect the components 12. The thickness is also sufficient to enable easy handling.

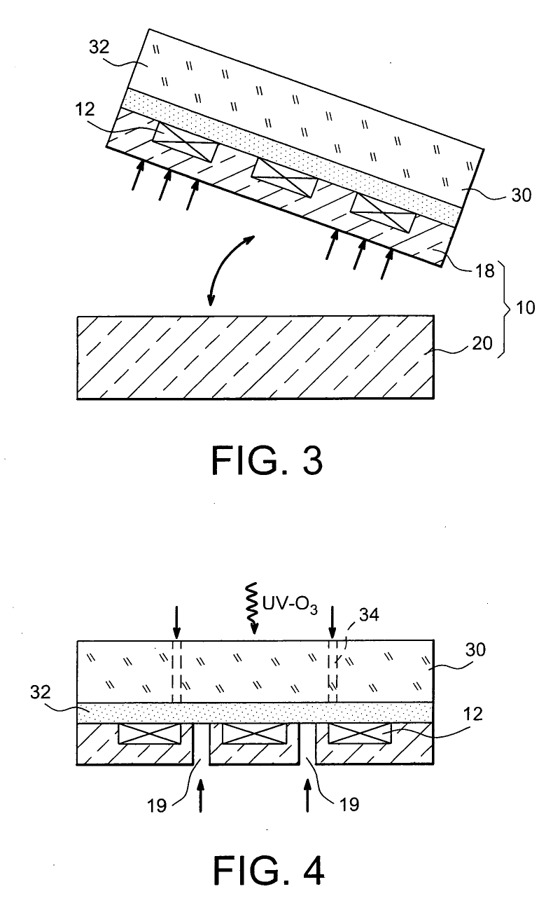

FIG. 3 shows a thinning treatment for the donor substrate 10. The thinning treatment comprises cleaving of the substrate along the fragilised zone in order to detach the solid part 20. The upper part 18 also undergoes thinning by abrasion. The abrasion, indicated just by small arrows, takes place on the freed face of the upper part 18, meaning the face opposite that in contact with the layer of glue 32. Another thinning means consists of consuming the substrate by mechanic-chemical polishing, for example, or by rectification or further by chemical attack.

During this treatment, the upper part 18 and the components 12 are not destroyed despite their possible thinness. In fact they are held firm by the handle substrate 30. The thinned upper part 18 and the components constitute the elements to be transferred, within the meaning of the invention.

FIG. 4 also shows a supplementary treatment that includes cutting out the upper layer 18 by making grooves 19. The grooves 19 cross through the layer 18 and make it possible to individualise the components 12.

FIG. 4 also shows the degradation of the glue layer 32. Heat treatment at a temperature of the order of 300° C., or ultraviolet UV treatment coupled or not with a gaseous agent such as O₃ facilitates reduction of the resistance of the layer of glue 32 by 50%, or more. Degradation can also be provoked by submitting the glue layer to the chemical action of a liquid solvent (acetone, trichlorethylene), a gaseous solvent or an etching agent, or further to the action of a supercritical fluid such as CO₂ for example. The chemical action is marked by small arrows. In this way, the grooves 19 provide excellent access to the layer of glue 32. Channels 34, indicated by broken lines, can also be provided in the handle substrate 30 for application of the solvent from the free face of this substrate. Preferably, degradation is continued until adherence is obtained that is lower than the adherence established afterwards between the transferred elements and the target substrate.

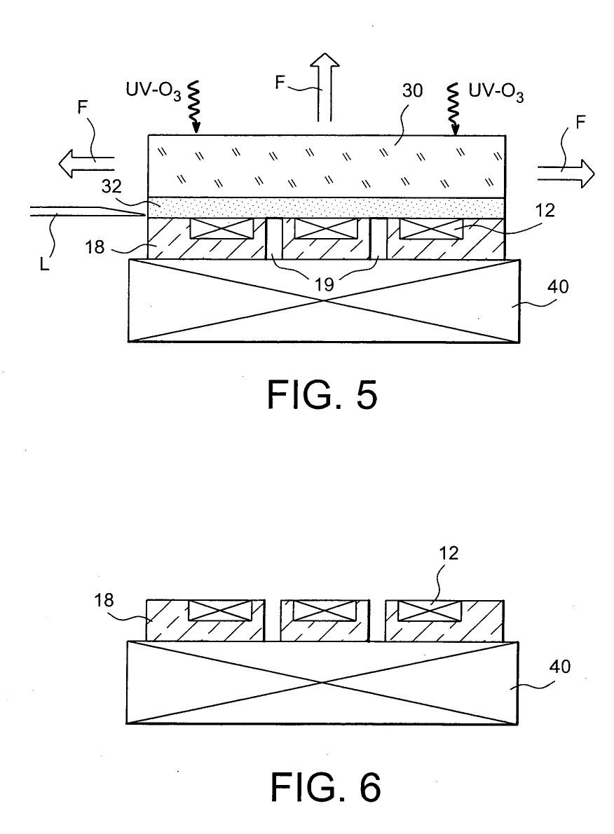

FIG. 5 shows the displacement of the elements to be transferred onto a target substrate 40. The target substrate 40 can be either a flexible or rigid substrate. As an example, it can consist of a chip card made of plastic material.

Displacement of the elements to be transferred can involve using a glue or, as in the example shown, by using direct molecular gluing. In this case, the free face of the layer 18 can first be submitted to chemical cleaning, polishing or dry activation so as to encourage direct adherence. These operations can be carried out before or after the formation of the grooves 19.

After displacement onto the target substrate, detachment of the handle substrate 30 is carried out. The arrows F indicate the tearing forces applied on the handle substrate 30, relative to the target substrate 40. Since the layer of glue 32 has already been degraded, it has an adherence generally lower than that existing between the elements to be transferred and the target substrate. Thus, tearing occurs along the glue layer 32. Reference L indicates a blade that can be inserted at the level of the layer of glue 32 or a punch passing through the processed handle. If necessary, this makes it possible to lighten the stress applied to the adherence interface between the elements to be transferred and the target substrate.

FIG. 6 shows the structure obtained after tearing and eliminating the handle substrate. A complementary cleaning treatment can eliminate any residues of glue on the components. The device of FIG. 6 can also be subject to a processing. Finally, contacts can be provided on the components if electronic components are involved.

Even though FIGS. 5 and 6 illustrate a collective transfer of components 12, it is possible to envisage selective transfer by making a smaller number of components adhere to the target substrate 40. After thinning the donor substrate in collective fashion (up to the level of the components), the elements are cut out as well as the handle, in such a way as to obtain individual objects. The glue is then degraded (a variant consists of degrading the glue before cutting out). After this, the individual objects can be manipulated with standard tools and displaced onto their final support. Next, the handle end of each transferred object is detached. Several operations for displacement and tearing are therefore envisaged for successive freeing of the components.

Thus, the method implies degradation of the layer of glue (which can be called the first gluing) before displacement of the element to be transferred onto the target substrate (which can be called the second gluing). This method of operation has certain advantages.

First of all, the second gluing is not damaged by the degradation step (by heat, chemical, radiation treatment . . . ) because this takes place before the second gluing. One is therefore free to choose the method for the second gluing. In particular, the second gluing means can be sensitive to the degradation means chosen for degrading the first gluing (if the choice has been made to separate at the level of the first layer of glue degraded by localised means, for example a mechanism that does not damage the second gluing).

Moreover, if the second gluing is molecular adhesion gluing, this gluing needs to be reinforced by heat treatment. If the first gluing zone has not been degraded before this treatment, it can itself be strengthened by said heat treatment until it reaches a threshold after which it can no longer be degraded. It is therefore important to carry out the degradation of the first gluing before the second gluing.

### Reference Documents

(1)
FR-A-2 809 867
(2)
FR-A-2 781 925
(3)
FR-A-2 796 491
(4)
T. Hamagushi et al. IEDM 1985 (pp. 688-691).

1. Method for transferring at least one element (12) from a donor substrate (10) to a target substrate (40), the element to be transferred being made integral with a handle substrate (30) through the intermediary of a layer of glue (32) whose adherence can be degraded, a degradation of the layer of glue (32) being carried out so as to free the element to be transferred (12), characterised in that it comprises the following successive steps:
a) gluing of the element to be transferred (12) from the donor substrate (10) onto the handle support (30) by the intermediary of the glue layer (32),
b) thinning of the donor substrate (10),
c) degradation of the adherence of the glue layer (32),
d) displacement of the element to be transferred (12) onto the target substrate (40),
e) separation of the element to be transferred and the handle substrate.

2. Method according to claim 1, wherein a glue used is chosen from among an epoxy glue, a glue to be hardened by ultraviolet radiation, a polymer base glue, or a glue with a wax base.

3. Method according to claim 1, wherein degradation of the glue layer is carried out by submitting it to a chemical treatment, a heat treatment, a radiation treatment and/or a plasma treatment.

4. Method according to claim 1, implemented for transferring a layer of material (18), and comprising a step for thinning the layer of material (18), the thinning being carried out when the layer of material (18) is integral with the handle substrate (30) and before degradation of the glue layer.

5. Method according to claim 4, comprising cutting out the layer of material (18) when the layer is integral with the handle substrate.

6. Method according to claim 1, wherein a handle substrate (30) is used with access paths (34) towards a face of the handle substrate able to be put into contact with the layer of glue.

7. Method according to claim 1 for selective transfer of components wherein the stages a) and b) are carried out collectively for an assembly of components and the stages c) and d) are repeated for sub-assemblies of components.

8. Method according to claim 1, wherein the detachment step includes applying traction, pressure, shearing, peeling or bending forces, or any combination of these forces, and/or the application of a jet of fluid and/or the insertion of a tapered object.
